(19) United States
(12) Patent Application Publication
(10) Pub. No.: US 2026/0043839 A1
(43) Pub. Date: Feb. 12, 2026

(54) Energy Harvesting Sensor Device Used to Detect Electrical Line Anomalies

(71) Applicant: US Department of Energy, Washington, DC (US)

(72) Inventors: Seong Choi, Lakewood, CO (US); Rishabh Jain, Denver, CO (US)

(21) Appl. No.: 18/795,448

(22) Filed: Aug. 6, 2024

(51) Int. Cl. G01R 31/08; H04N 7/18; H04N 23/698

(52) U.S. Cl. CPC G01R 31/085; H04N 7/183; H04N 23/698

(57) ABSTRACT

One or more embodiments relate to a sensor device used to proactively detect an electrical line anomaly, an anomaly detection system, and a method for detecting an anomaly in one or more electrical lines. The device includes an image capture device, and a processing unit communicating with at least the image capture device, where the processing unit is adapted to send out an alarm and future potential image/video.

### STATEMENT OF GOVERNMENT INTEREST

The United States Government has rights in this invention pursuant to Contract No. DE-AC36-08G028308 between the U.S. Department of Energy and the Alliance for Sustainable Energy, LLC. for the operation of the National Renewable Energy Laboratory.

### BACKGROUND OF THE INVENTION

The U.S. Government recognizes that a secure and resilient power grid is vital to national security, a strong economy, and services that the public relies on every day. In fact, the U.S. Department of Energy, acting through the Office of Electricity for example, works closely with private and public sectors to ensure that our critical power infrastructure is secure from both manmade and natural hazards.

Currently, disaster detection and prediction for issues such as wildfires, downed power lines, ice storms, and flooding, among others, is based on visual inspections, drone imagery, and/or satellite imagery. However, satellite images are not provided in real time, and during heavy weather conditions, neither drones can be flown nor inspections be conducted. Installing energy harvesting devices on electrical poles has been considered, but the costs are prohibitive. Finally, monitoring devices are used to monitor conditions at the substation level, however such devices are not predictive, but rather provide information after an event.

Embodiments of the invention may be used anywhere power infrastructure safety is important.

### SUMMARY OF THE INVENTION

One or more embodiments relate to a sensor device used to proactively detect an electrical line anomaly, an anomaly detection system, and a method for detecting an anomaly in one or more electrical lines. Exemplary embodiments monitor the situation 360° around one or more electrical lines and can include images, video, sound, Lidar, infrared, Radar, GPS, acceleration, gravity and/or weather information. Embodiments enable generating future images of what may happen around an electrical line and/or equipment if no action is taken. Embodiments enable providing an alarm to an operator and/or automated command device including at least images/video, if a predetermined threshold is met or exceeded. Additional embodiments may provide operational instructions or recommend action depending on the situation to the operator and/or automated command device.

One exemplary embodiment of the device includes an image capture device; and a processing unit communicating with at least the image capture device, where the processing unit is adapted to send out an alarm and future potential image/video.

Yet another embodiment relates to an anomaly detection system where the anomaly detection system includes at least one sensor device positioned on an electrical pole proximate one or more electrical lines and used to proactively detect an anomaly. The at least one sensor device includes an image capture device and a global positioning system device. Embodiments include a processing unit communicating with at least the image capture device and the global positioning system device, where the processing unit is adapted to send out an alarm, location, and future potential image/video. Additionally, one or more embodiments may include a control room sensor data concentrator communicating with at least the processing unit enabling an operator to mitigate the anomaly. One or more embodiments may include a local sensor data concentrator communicating with at least the processing unit and the control room sensor data concentrator adapted to generate an alarm and provide at least a predictive image/video to the control room sensor data concentrator.

Still another embodiment relates to a method for detecting an anomaly in one or more electrical lines. Embodiment of the method may include proactively detecting an anomaly of the one or more electrical lines using at least one sensor device positioned on an electrical pole proximate the one or more electrical lines; generating an alarm and providing a predictive image/video; and mitigating the anomaly.

It should be appreciated that one or more embodiments of the sensor device may include a 360° camera, a sound detection device, a temperature-sensing device, a gravity-sensing device, an infrared detection device, and/or a motion-detecting device communicating with at least the processing unit. Additional embodiments may include a weather-detecting device, an accelerometer detection device, a Lidar device, a Radar sensor device, and/or a global positioning system device communicating with at least the processing unit.

### BRIEF DESCRIPTION OF DRAWINGS

These and other features, aspects, and advantages of the multiple embodiments of the present invention will become better understood with reference to the following description, appended claims, and accompanied drawings where:

FIG. 1 depicts a schematic diagram of an anomaly detection system in accordance with one embodiment;

FIG. 2 depicts a schematic diagram of a sensor device used in an anomaly detection system of FIG. 1 in accordance with one embodiment;

FIG. 3 depicts a schematic diagram of a control room sensor data concentrator used in an anomaly detection system of FIG. 1 in accordance with one embodiment;

FIGS. 4A-4J depict images of environmental issues prior to an actual disaster; where FIG. 4A depicts a tree touching a power line but no arcing, FIG. 4B depicts a pole and power line down but no fault, FIG. 4C depicts a tree touching a line and the power line arcing, FIG. 4D depicts a flooding level proximate a power line, FIG. 4E depicts a tornado proximate a power line, FIG. 4F depicts an ice storm, FIG. 4G depicts a power line sagging, FIG. 4H depicts a tree branch swinging proximate a power line, FIG. 4I depicts a tree branch swinging proximate a power line due to extremely high winds, and FIG. 4J depicts a cracked or broken pole; and

FIG. 5 depicts a flow chart illustrating a method for detecting an anomaly in one or more electrical lines.

### DETAILED DESCRIPTION OF THE INVENTION

The following description is provided to enable any person skilled in the art to use the invention and sets forth the best mode contemplated by the inventor for carrying out the invention. Various modifications, however, will remain readily apparent to those skilled in the art. One or more embodiments relate to a sensor device used to proactively detect an electrical line anomaly, an anomaly detection system, and a method for detecting an anomaly in one or more electrical lines.

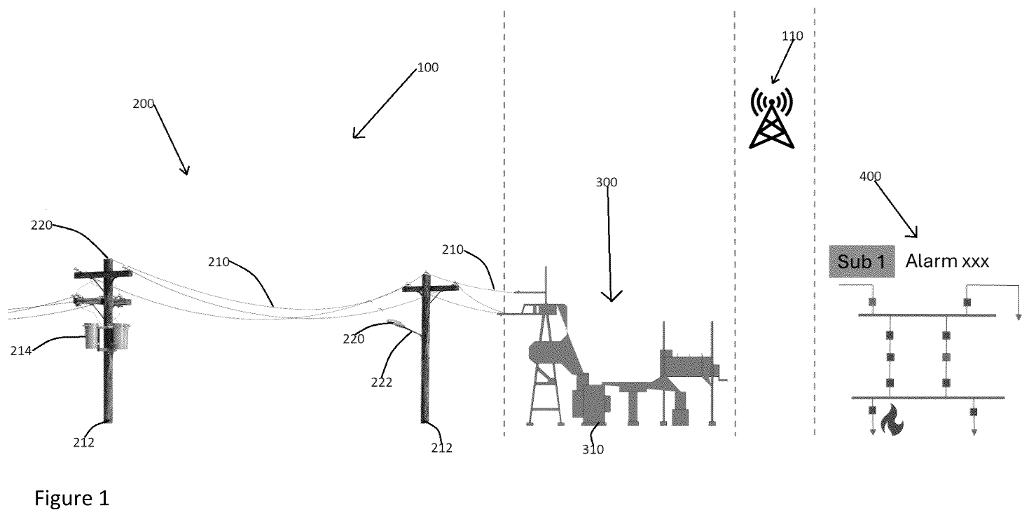

Referring now to FIG. 1, a schematic diagram of an anomaly detection system, generally designated 100, is depicted in accordance with one embodiment. As illustrated, an exemplary embodiment of the anomaly detection system 100 includes power line infrastructure 200 in communication with one or more local sensor data concentrators 300 which are in communication with one more control room sensor data concentrators 400.

FIG. 1 illustrates that power line infrastructure 200 includes one or more electrical lines 210. It should be appreciated that in the illustrated embodiment, infrastructure 200 includes one or more electrical or utility poles 212 supporting electrical lines 210 and having one or more transformers 214. In this embodiment, infrastructure 200 includes one or more sensor devices 220 positioned proximate the one or more electrical lines 210. FIG. 1 illustrates that the sensor devices 220 may be positioned on top of a pole 212 or attached to a pole arm 222 extending from the utility pole 212, however other embodiments are contemplated. For example, the sensor devices 220 could be attached to one of the electrical lines 210 or depend therefrom.

FIG. 1 further illustrates that one or more local sensor data concentrators 300 coupled to and in communication with the power line infrastructure 200 via electrical lines 210, although other means are contemplated including wireless communications, for example. The one or more local sensor data concentrators 300 may include one or more predictive image, alarm generation, and/or power measurement devices 310. In one or more embodiments, the devices 310 generate an alarm about a predetermined threshold which is transmitted to an operator with one or more future potential images/video.

Additionally, FIG. 1 illustrates one or more control room sensor data concentrators 400 wirelessly coupled to and communicating with the one or more local sensor data concentrators 300 via wireless network 110. Although wireless communications are shown, wired communications are contemplated.

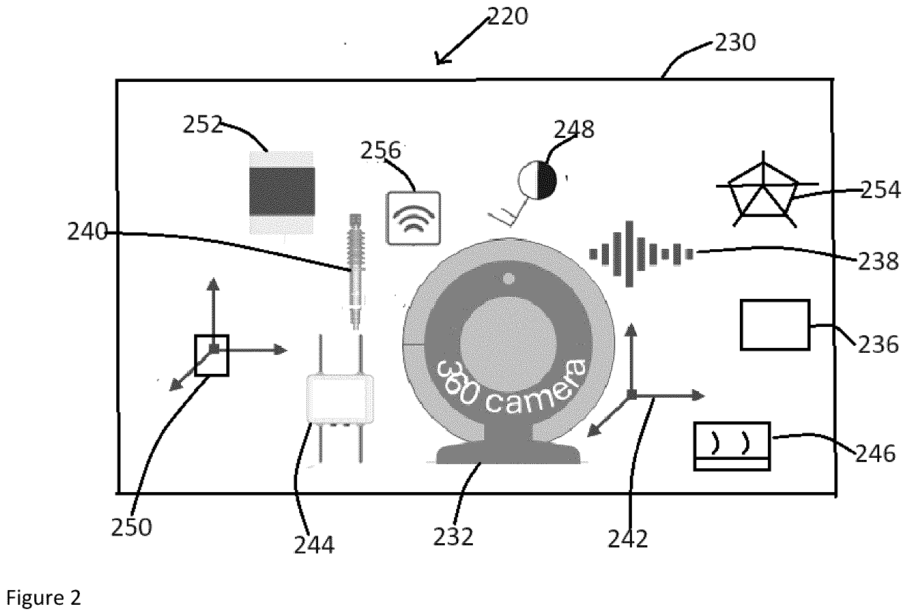

FIG. 2 depicts a schematic diagram of a sensor device 220 in the anomaly detection system 100 of FIG. 1 and adapted to proactively detect an electrical line anomaly in accordance with one embodiment. In the illustrated embodiment, sensor device 220 includes a weather-tight housing 230. Device 220 includes at least an image capture device 232, a 360° camera for example, communicating with a processing unit 236, the processing unit 236 adapted to send out an alarm and future potential image/video. One or more embodiments of the device 220 includes a sound detection device 238, a temperature-sensing device 240, a gravity-sensing device 242, an infrared detection device 244, a motion-detecting device 246, a weather-detecting device 248, an accelerometer detection device 250, a Lidar device 252, Radar sensor device 254, and/or GPS device 256, one or more of which communicate with at least the processing unit 236 wirelessly or hardwired connections.

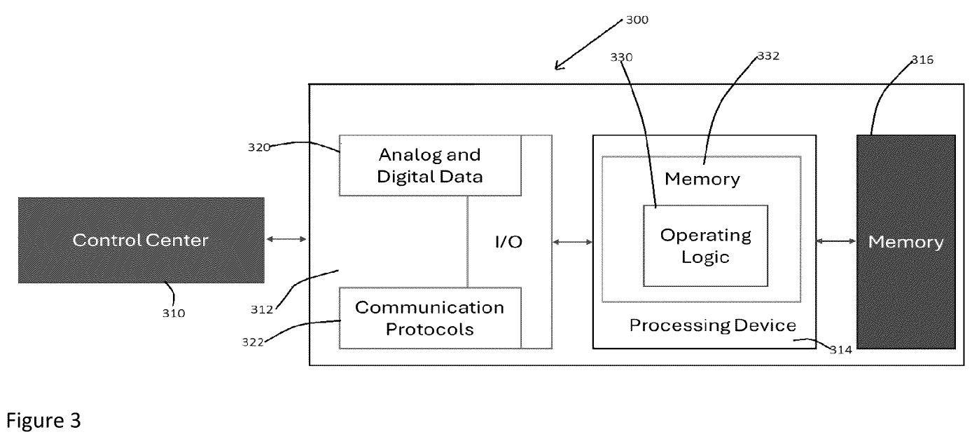

FIG. 3 depicts a schematic diagram of one embodiment of a control room sensor data concentrator 300 used in the anomaly detection system 100 of FIG. 1. FIG. 3 illustrates the control center 310 communicating with the control room sensor data concentrator 300. In the exemplary embodiment shown the control room sensor data concentrator 300 includes one or more I/O devices 312, one or more processing devices 314 communicating with the I/O devices 312, and one or more memories 316 communicating with the processing devices 314.

In one embodiment, the one or more I/O Devices 312 includes analog and digital data 320 and communication protocols 322. The one or more processing devices 314 including operating logic 330 and memory 332 and is depicted communicating with the I/O devices 312 and memory 316. Embodiments may generate one or more alarms, enabling one or more operators to be forewarned of an upcoming incident and recommend operational instructions and responses. Such responses may include lowering current to avoid arcing, re-routing power, and/or sending alerts to potentially impacted customers.

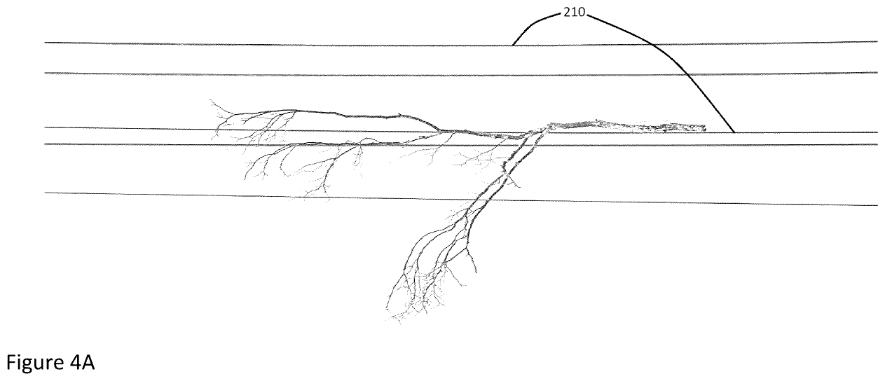

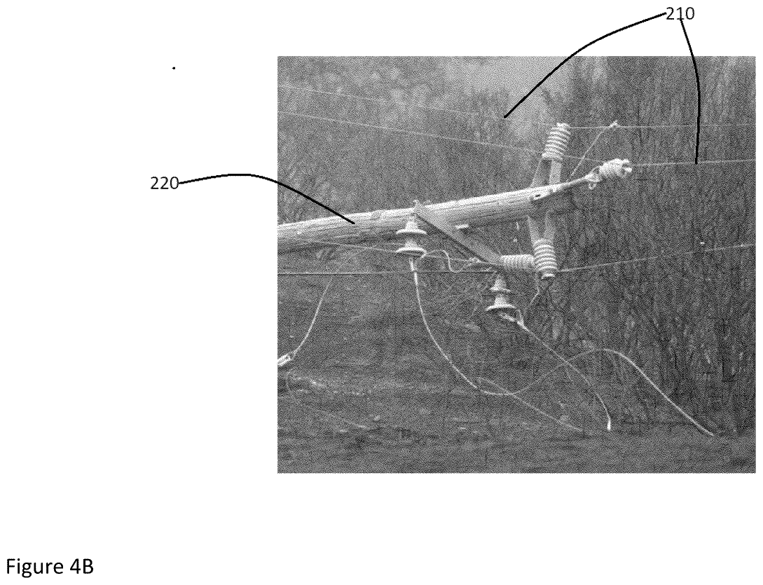

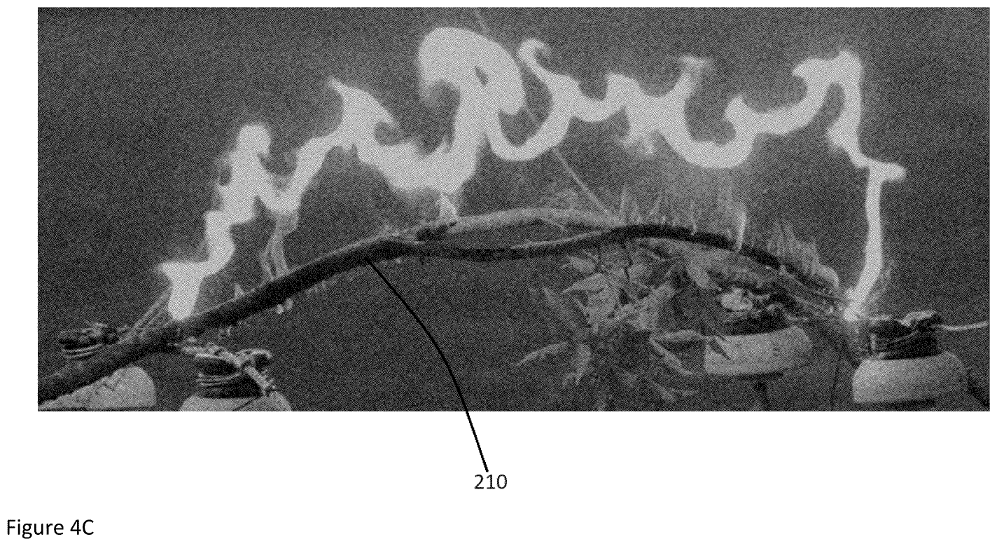

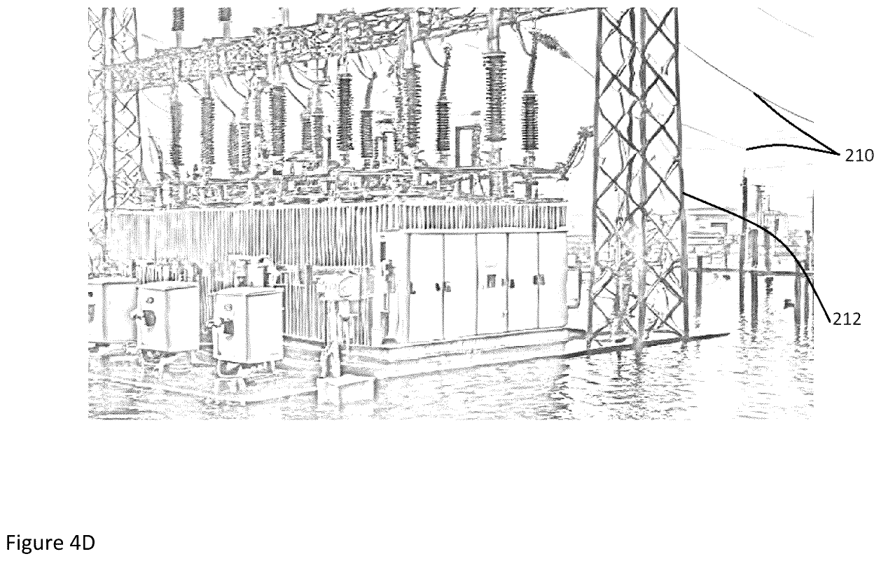

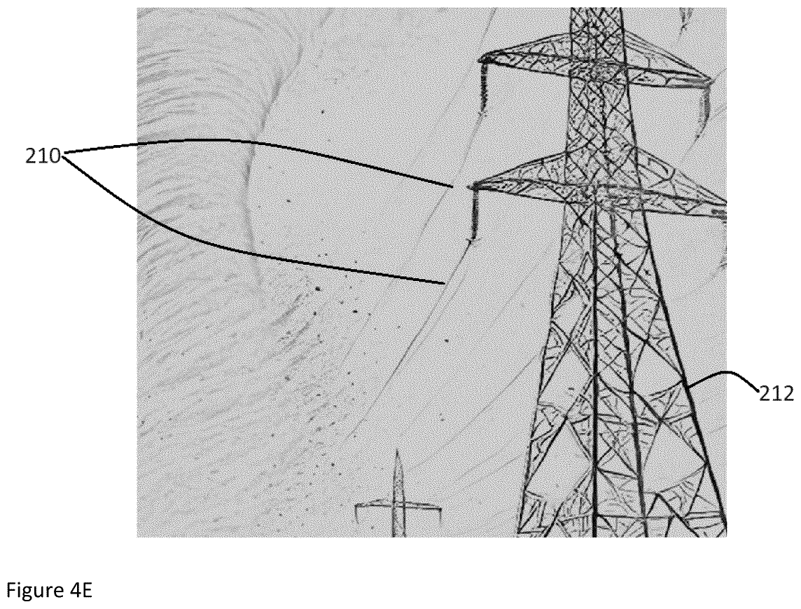

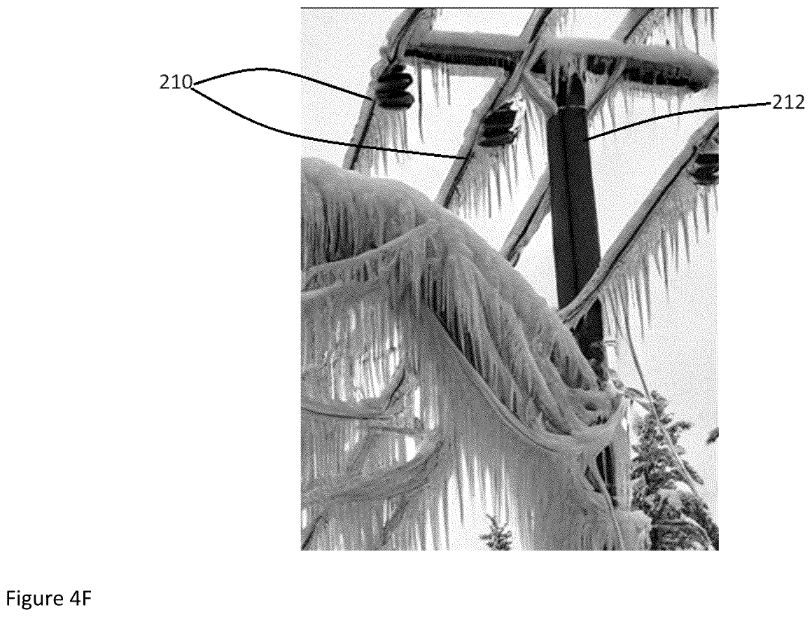

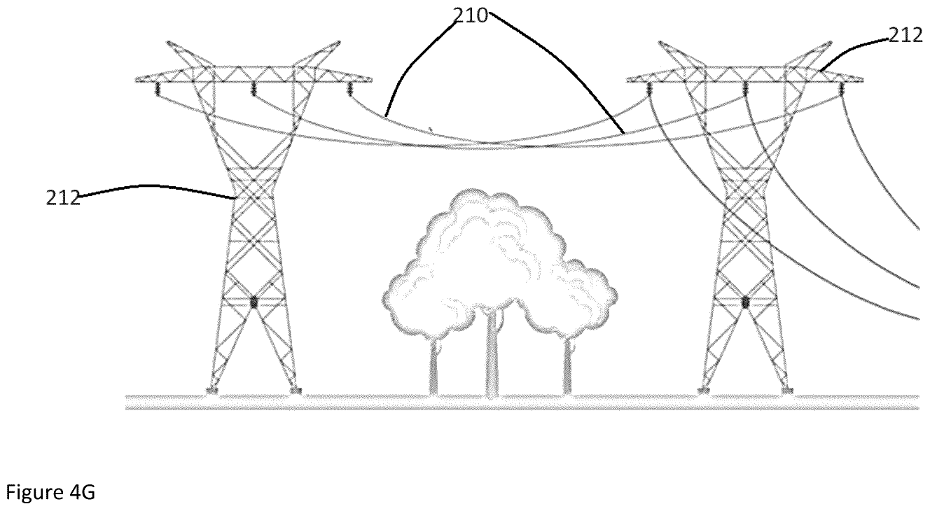

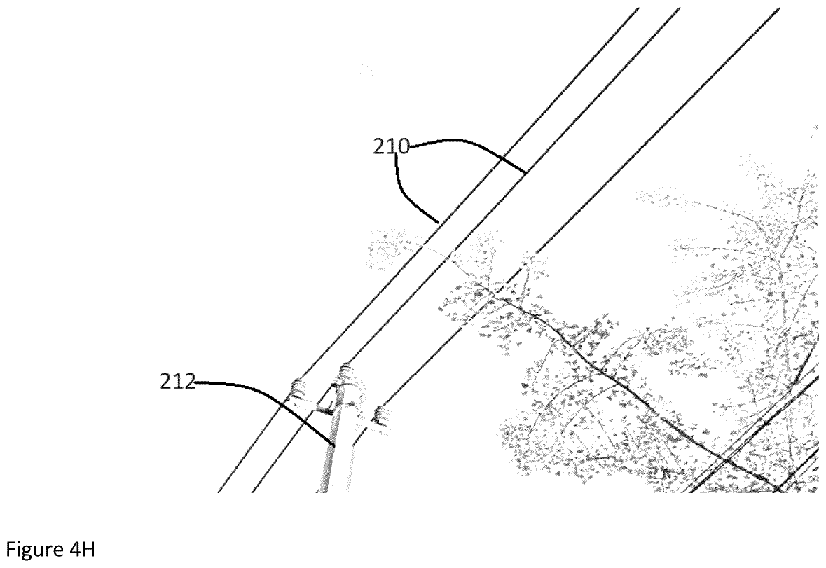

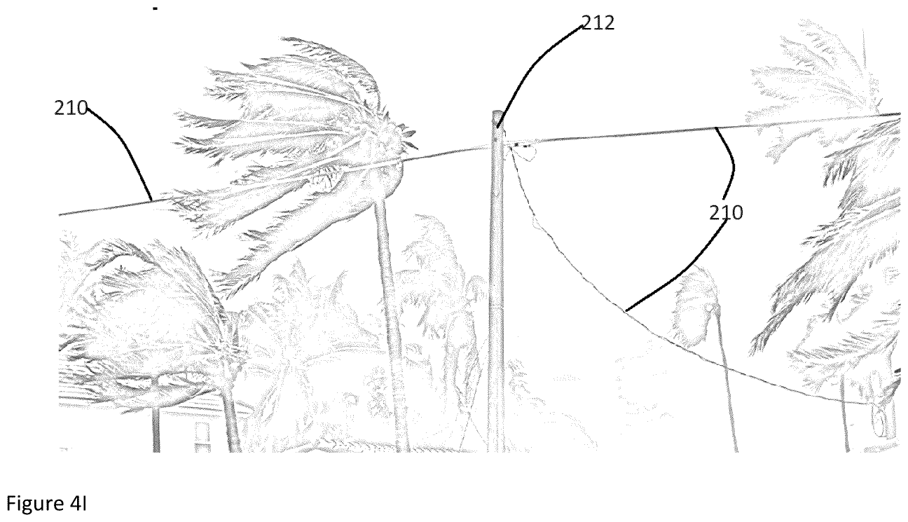

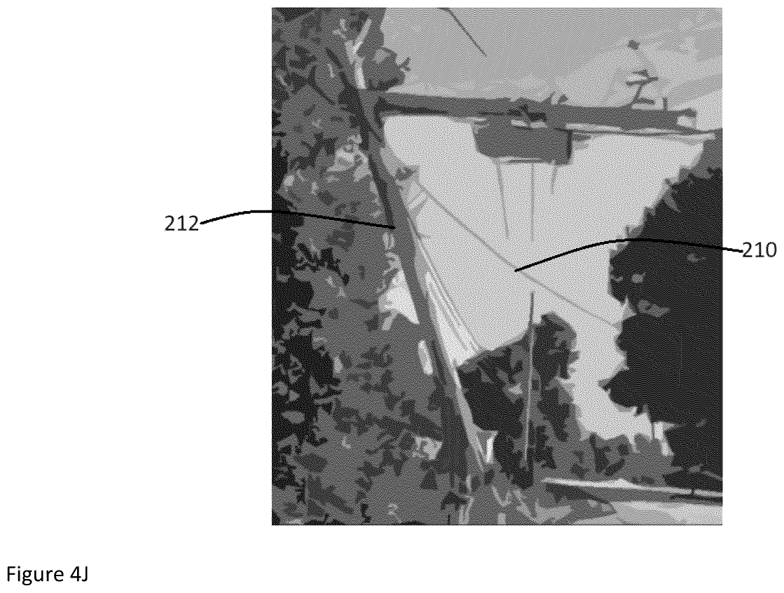

FIGS. 4A-4J depict examples of images/video of environmental issues system 100 may generate prior to an actual incident (5 to 10 minutes prior but other time periods are contemplated. FIG. 4A depicts a tree touching a power line 210 but no arcing and FIG. 4B depicts a pole 212 and power line 210 down but no fault where the pole 212 may have been struck by a car or truck for example. FIG. 4C depicts a tree branch touching power line 210 and the power line 210 arcing. FIG. 4D depicts a flooding level proximate pole 212, while FIG. 4E depicts a tornado proximate pole 212 and power line 210. FIG. 4F depicts an ice storm where the power lines 210 sag due to the weight of the ice. FIG. 4G depicts a power line 210 sagging due to its weight or stress for example. FIG. 4H depicts a tree branch swinging proximate a power line 210 while FIG. 4I depicts a tree branch swinging proximate a power line 210 due to extremely high winds. FIG. 4H depicts a cracked or broken pole 212 (due to age for example) and a power line 210 down.

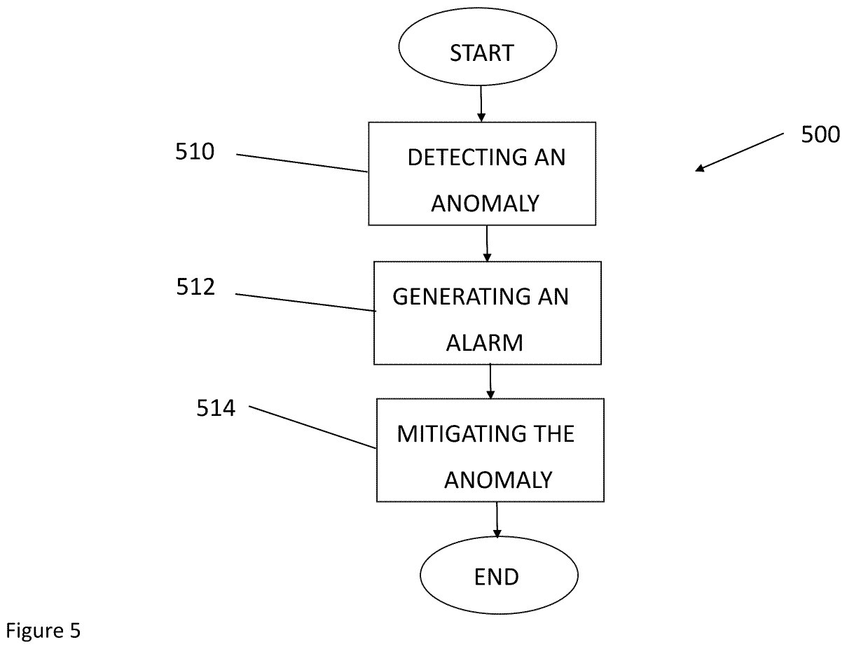

FIG. 5 depicts a flow chart illustrating a method for detecting an anomaly in one or more electrical lines, generally designated 500. One embodiment of method 500 includes proactively detecting an anomaly of the one or more electrical lines using at least one sensor device positioned on an electrical pole proximate the one or more electrical lines, block 510. Embodiments include generating an alarm and providing a predictive image/video, block 512; and mitigating the anomaly, block 514. Embodiments may generate one or more alarms, enabling one or more operators to be forewarned of an upcoming incident and recommend operational instructions and responses. Such responses may include lowering current to avoid arcing, re-routing power, and/or sending alerts to potentially impacted customers.

Having described the basic concept of the embodiments, it will be apparent to those skilled in the art that the foregoing detailed disclosure is intended to be presented by way of example. Accordingly, these terms should be interpreted as indicating that insubstantial or inconsequential modifications or alterations and various improvements of the subject matter described and claimed are considered to be within the scope of the spirited embodiments as recited in the appended claims. Additionally, the recited order of the elements or sequences, or the use of numbers, letters or other designations therefor, is not intended to limit the claimed processes to any order except as may be specified. All ranges disclosed herein also encompass any and all possible sub-ranges and combinations of sub-ranges thereof. Any listed range is easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as up to, at least, greater than, less than, and the like refer to ranges which are subsequently broken down into sub-ranges as discussed above. As utilized herein, the terms “about,” “substantially,” and other similar terms are intended to have a broad meaning in conjunction with the common and accepted usage by those having ordinary skill in the art to which the subject matter of this disclosure pertains. As utilized herein, the term “approximately equal to” shall carry the meaning of being within 15, 10, 5, 4, 3, 2, or 1 percent of the subject measurement, item, unit, or concentration, with preference given to the percent variance. It should be understood by those of skill in the art who review this disclosure that these terms are intended to allow a description of certain features described and claimed without restricting the scope of these features to the exact numerical ranges provided. Accordingly, the embodiments are limited only by the following claims and equivalents thereto. All publications and patent documents cited in this application are incorporated by reference in their entirety for all purposes to the same extent as if each individual publication or patent document were so individually denoted.

All numeric values are herein assumed to be modified by the term “about”, whether or not explicitly indicated. The term “about” generally refers to a range of numbers that one of skill in the art would consider equivalent to the recited value (e.g., having the same function or result). In many instances, the terms “about” may include numbers that are rounded to the nearest significant figure.

The recitation of numerical ranges by endpoints includes all numbers within that range (e.g. 1 to 5 includes 1, 1.5, 2, 2.75, 3, 3.80, 4, and 5).

One skilled in the art will also readily recognize that where members are grouped together in a common manner, such as in a Markush group, the present invention encompasses not only the entire group listed as a whole, but each member of the group individually and all possible subgroups of the main group. Accordingly, for all purposes, the present invention encompasses not only the main group, but also the main group absent one or more of the group members. The present invention also envisages the explicit exclusion of one or more of any of the group members in the claimed invention.

1. A sensor device used to proactively detect an electrical line anomaly, the device comprising:
an image capture device; and
a processing unit communicating with at least the image capture device, the processing unit adapted to send out an alarm and future potential image/video.

2. The sensor device of claim 1 wherein the image capture device comprises a 360° camera communicating with at least the processing unit.

3. The sensor device of claim 1 further comprising a sound detection device communicating with at least the processing unit.

4. The sensor device of claim 1 further comprising a temperature-sensing device communicating with at least the processing unit.

5. The sensor device of claim 1 further comprising a gravity-sensing device communicating with at least the processing unit.

6. The sensor device of claim 1 further comprising an infrared detection device communicating with at least the processing unit.

7. The sensor device of claim 1 further comprising a motion-detecting device communicating with at least the processing unit.

8. The sensor device of claim 1 further comprising a weather-detecting device communicating with at least the processing unit.

9. The sensor device of claim 1 further comprising an accelerometer detection device communicating with at least the processing unit.

10. The sensor device of claim 1 further comprising a Lidar device communicating with at least the processing unit.

11. The sensor device of claim 1 further comprising a Radar sensor device communicating with at least the processing unit.

12. The sensor device of claim 1 further comprising a global positioning system device communicating with at least the processing unit.

13. An anomaly detection system, the anomaly detection system comprising:
at least one sensor device positioned on an electrical pole proximate one or more electrical lines used to proactively detect an anomaly, the at least one sensor device comprising:
an image capture device;
a global positioning system device; and
a processing unit communicating with at least the image capture device and the global positioning system device, the processing unit adapted to send out an alarm, location, and future potential image/video; and
a control room sensor data concentrator communicating with at least the processing unit enabling an operator to mitigate the anomaly.

14. The anomaly detection system of claim 13 further comprising a local sensor data concentrator communicating with at least the processing unit and the control room sensor data concentrator adapted to generate an alarm and provide at least predictive image/video to the control room sensor data concentrator.

15. The anomaly detection system of claim 13 wherein the image capture device comprises a 360° camera communicating with at least the processing unit.

16. The anomaly detection system of claim 13 wherein the sensor device further includes a sound detection device communicating with at least the processing unit.

17. The anomaly detection system of claim 13 wherein the sensor device further includes a temperature-sensing device communicating with at least the processing unit.

18. The anomaly detection system of claim 13 wherein the sensor device further includes a gravity-sensing device communicating with at least the processing unit.

19. The anomaly detection system of claim 13 wherein the sensor device further includes an infrared detection device communicating with at least the processing unit.

20. The anomaly detection system of claim 13 wherein the sensor device further includes a motion-detecting device communicating with at least the processing unit.

21. The anomaly detection system of claim 13 wherein the sensor device further includes a weather-detecting device communicating with at least the processing unit.

22. The anomaly detection system of claim 13 wherein the sensor device further includes an accelerometer detection device communicating with at least the processing unit.

23. The anomaly detection system of claim 13 wherein the sensor device further includes a Lidar device communicating with at least the processing unit.

24. The anomaly detection system of claim 13 wherein the sensor device further includes a Radar sensor device communicating with at least the processing unit.

25. A method for detecting an anomaly in one or more electrical lines, the method comprising:
proactively detecting an anomaly of the one or more electrical lines using at least one sensor device positioned on an electrical pole proximate the one or more electrical lines;
generating an alarm and providing a predictive image/video; and
mitigating the anomaly.
